(19) United States
(12) Patent Application Publication
(10) Pub. No.: US 2002/0164419 A1
(43) Pub. Date: Nov. 7, 2002

(54) Fabrication of self-assembled monolayers

(76) Inventors: Hitoshi Fukushima, Tsukuba-city (JP); Satoru Miyashita, Chino-shi (JP); Masaya Ishida, Nagano-ken (JP); Andrew Holmes, Cambridge (GB); Wilhelm Huck, Comberton (GB)

Correspondence Address: HARNESS, DICKEY & PIERCE, P.L.C., P.O. BOX 828, BLOOMFIELD HILLS, MI, 48303, US

(21) Appl. No.: 10/005,175

(22) Filed: Dec. 3, 2001

(30) Foreign Application Priority Data
Dec. 4, 2000 (GB) 0029535.2

(51) Int. Cl. C23C 16/00

(52) U.S. Cl. 427/248.1

(57) ABSTRACT

A self-assembled monolayer (SAM) is fabricated using either a semi-fluorinated sulphur containing compound, or a sem-fluorinated silane derivative and compressed carbon dioxide (CO₂) as the solvent medium. The temperature and/or pressure of the compressed CO₂ may be varied during the fabrication process to improve the molecular packing density of the monolayer.

By using compressed CO₂ as the solvent medium, monolayers with good molecular packing density can be fabricated relatively quickly without the use of environmentally unfriendly solvents.

The present invention relates to a method of fabricating self-assembled monolayers onto a substrate and to products including such monolayers.

Self-assembled monolayers (SAMs) have attracted much attention in areas such as device engineering because of the versatility they provide for surface modification. SAMs are highly ordered molecular assemblies that form spontaneously by chemisorption of functionalised molecules on a variety of substrates such as metals, Indium Tin Oxide (ITO), silicon, and glass. These molecules organise themselves laterally, most commonly via van der Waals interactions between long aliphatic chains. The principles and practice of deposition of monolayers are described in detail in a publication by A Ulman entitled “Introduction to Thin Organic Films: From Langmuir-Blodgett to Self-Assembly”, published by Boston Academic Press, 1991. SAMs have found widespread research interest because of potential applications related to control over wettability, biocompatibility and corrosion resistance of surfaces.

For many electronic, optical and electro-optical devices for example, the ability to modify the properties of surface areas of the devices makes SAMs attractive for many applications, such as modification of surface hydrophobicity, packaging and electrical insulation. Furthermore, as SAMs exhibit excellent barrier properties, they are considered very appropriate for use as protective coatings on metal surfaces because they form thin highly crystalline barrier films. Gold has found widespread application and, for example, is used extensively in the electronics industry in integrated circuit technology. Also, as a relatively inert metal it has also been used as a protective layer in certain chemical environments, such as a liner material for the ink chambers in ink jet print heads. However, gold will dissolve under appropriate chemical or electrochemical conditions, so the ability of SAMs to provide a very thin protective layer to such metal layers in harsh chemical environments where metal layer corrosion is known to occur is also considered extremely attractive. However, SAMs have been found to exhibit certain drawbacks which, to date, have severely limited their commercial application in industrial processes.

To date, the SAM material is deposited by dissolving the material in an appropriate solvent and, as such, the monolayer formation over the required flat surface areas, which usually include surface discontinuities arising from design features dictated by the practical application of devices, is difficult to control. As the layers are self aligning, they often exhibit molecular sized defects or holes in the layer. These defects can limit their use as barrier or passivation layers in certain industrial applications because the barrier properties provided by the densely packed molecules of the SAM material can be breached through the molecular sized defects.

Furthermore, although SAMs are typically in the order of only about 2 nm thickness, they are relatively slow to deposit. Typical deposition times range from several hours to a few days with the normal solvents used for the compounds. Heavily fluorinated compounds, such as thiols carrying aliphatic tails with multiple fluorine substituents, have been used to form very hydrophobic SAMs on gold substrates. A measure for the hydrophobicity of a surface is the contact angle between a drop of water and that surface. Contact angles for water on fluorinated SAM surfaces can be as high as 125°. These SAMs are quite robust and are stable up to 150° C. as described by Fukushima et al in The Journal of Physical Chemistry, B, (2000) 104, pages 7417 to 7423, so it can be appreciated that such monolayers could find widespread industrial application if the concerns associated with fabrication can be met.

However, such heavily fluorinated compounds are rather insoluble in most organic solvents but can be processed in halogenated or perfluorinated solvents e.g. dichloromethane, trifluoromethanol, or perfluoroalkanes. The use of such perfluorinated solvents in combination with other immiscible solvents for synthesis has been termed ‘fluorous biphase chemistry’. Disadvantages of these solvents include their toxicity, price and adverse impact on atmospheric chemistry. SAMs have also been fabricated on silicon substrates using semi-fluorinated silane derivatives. However, SAMs of these compounds are usually deposited by way of a vapour deposition process which is very time consuming.

These very significant concerns, and in particular those relating to the types of solvents used and their long deposition times, have severely restricted the practical adoption of SAMs in industrial applications. This is particularly surprising when considering the significant benefits that are known to accrue from the use of SAMs.

Compressed carbon dioxide (CO₂) is known to be a clean and versatile solvent medium for a wide range of materials, including heavily fluorinated compounds. Supercritical CO₂ has been used for polymer synthesis and polymer processing. Such use is described in an article by A Cooper entitled “Polymer Synthesis and Processing using Supercritical Carbon Dioxide”, published in The Journal of Materials Chemistry, 2000, 10, pages 207 to 234. A supercritical fluid may be defined as a substance for which both temperature and pressure are above the critical values for the substance and which has a density close to or higher than its critical density. For CO₂, the critical density is recognised to be 0.47 g cm⁻³, and the critical temperature and pressure are recognised to be 31.1° C. and 73.8 bar. Compressed CO₂ has also been proposed as a solvent for the preparation of organic molecules, as described in a Special Issue of Chemical Review, 1999, 99 Volume 2.

U.S. Pat. No. 5,725,987 describes a process for the preparation of toner additives in which the additives are surface treated using supercritical CO₂. The additives are usually in the form of fine powders with particle sizes in the range of from about 5 to about 500 nanometers and they are treated to render the particles hydrophobic and more suitable for use as a toner binder. U.S. Pat. No. 5,725,987 describes, therefore, one application in which supercritical CO₂ can be used as a solvent for a coating composition; in this instance, a coating composition used to coat very small size colloidal particles.

Dispersing agents that are similar to the surfactants described in the context of the present invention, but lacking the chemical functionalities to adhere to solid surfaces, have been used in the reactions described above. U.S. Pat. No. 5,780,565, U.S. Pat. No. 5,733,964 and U.S. Pat. No. 5,840,620 disclose the use of dispersing agents in polymerisation, polymer processing and olefin metathesis reactions, respectively. Additionally, a tiolated fluorocarbon (1H,1H,2H,2H-perfluorodecanethiol) has been used as a stabilising agent in the production of gold colloids in aqueous acetone. The resulting fluorocarbon coating is able to facilitate the dispersion of the nanoclusters in compressed CO₂. This process is described by Shah et al in the Journal of American Chemical Society (2000 122, 4245). This is another example of the well known ability of fluorinated surfactants to stabilise dispersions in carbon dioxide. Moreover, the chemical modification of metal oxide particles with organosilane compounds in supercritical carbon dioxide was demonstrated to render the susceptible properties of surfaces into stable and intact dispersed conditions. This method was described by Combes et al in Langmuir (1999 15, 7870). However, the formation of SAMs in compressed CO₂ has not been described or suggested (as the key concept) previously in spite of the above described applications of compressed CO₂ as a solvent and the considerable and longstanding concerns associated with the fabrication of SAMs, which have severely hindered their commercial application.

It has now been realised with the present invention that compressed CO₂ can advantageously be used as a solvent for the preparation of monolayers. This is particularly beneficial because it is inexpensive, non-toxic and non-flammable. Additionally, unlike conventional liquid solvents, compressed CO₂ is highly compressible and the density (and therefore solvent properties) can be tuned over a wide range by varying the pressure.

The present invention seeks to provide, therefore, a method that uses compressed CO₂ as a solvent to form self-assembled monolyers based on multiple fluorinated compounds, for example, to generate hydrophobic surfaces. The improved solubility of the fluorinated compounds facilitates the interaction of these molecules with the substrate and hence facilitates the formation of the SAMs. This is considered particularly important with SAMs where the surface integrity of the monolayers, i.e not exhibiting molecular sized defects in the extremely thin layer, is considered to be of paramount importance. Additionally, with the present invention, the speed at which the various SAMs can be formed over the required flat surfaces has been found to particularly beneficial. Good quality SAMs can be fabricated in a matter of minutes to hours, rather than conventional preparation times of several hours to days with the use of conventional solvents.

Further advantages are also provided in that these surfaces can be made heat and solvent resistant, and their deposition avoids the use of environmentally unfriendly solvents.

According to a first aspect of the present invention, there is provided a method of fabricating a self-assembled monolayer of a substance on a substrate comprising depositing the substance on the substrate using compressed carbon dioxide as the solvent medium for the substance.

Advantageously, the pressure and/or temperature of the compressed carbon dioxide is/are selectively controlled so as to enhance the density of the self-assembled monolayer on the substrate.

Preferably, a co-solvent is used in combination with the compressed carbon dioxide.

In a preferred embodiment, the substrate comprises a metallic substance such as gold silver, copper, iron, mercury, palladium, gallium arsenide, ferrous oxide, indium tin oxide.

Most preferably, the substance comprises a semi-fluorinated sulphur containing compound having a formula as defined in claim 7 appended hereto.

In an alternative embodiment the substrate comprises at least one of glass, mica, SiO₂, Al₂O₃, or Ga₂O₃.

Preferably, the substance comprises a semi-fluorinated silane derivative having a formula as defined in claim 17 appended hereto.

In an alternative aspect of the present invention, there is provided an inkjet head comprising a self-assembled monolayer in accordance with the first aspect of the invention as defined above.

In a further aspect of the present invention, there is provided an electronic, optical or optoelectronic device comprising a self-assembled monolayer in accordance with the first aspect of the invention defined above.

Preferably, the device may comprise a thin film transistor, an organic semi-conductor device, or a light emitting diode, which advantageously may be an organic polymer light emitting diode.

The present invention will now be described by way of further example only.

SAMs have been fabricated on metallic, glass and silicon type substrates. For metallic substrates, which may consist of a layer of Au, Ag, Cu, Pd, Fe, Hg, GaAs, ITO, or Fe₂O₃ on a suitable supporting medium, the SAM may typically comprise a substance including semi-fluorinated sulphur-containing compounds of the formula:

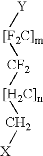

wherein X can be (but is not necessarily limited to) R—SH, RS—SR, or R—S—R (where R denotes the rest of the molecule). Preferably, disulphides are used and most preferably X is a thiol.

The numbers m and n denote the number of fluorinated and non-fluorinated carbon atoms, respectively, and lie within the range of 1-20. Preferably, m and n fall within the range of 5-10, and most preferably, m=8 and n=10. Y preferably indicates a CF₃ functional group. Y may be further modified to incorporate one or more substituents such as, vinyl, styryl, acryloyl, methacryloyl or alkyne for further functionalisation or cross-linking, with one or more spacer group such as CH₂ to facilitate attachment.

Self-assembled monolayers on glass, mica, SiO₂, Al₂O₃, or Ga₂O₃ typically involve semi-fluorinated silane derivatives of the formula:

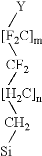

Wherein Si can be (but is not necessarily limited to) SiCl₃, Si(OCH₃)₃, Si(OCH₂CH₂CH₃)₃, Si(OCH₃)₂Cl, or Si(CH₂CH₃)₂Cl. Preferably, Si is a trialkoxy derivatives and most preferably, Si is SiCl₃. The numbers m and n denote the number of fluorinated and non-fluorinated carbon atoms, respectively, and lie within the range of 1-20. Preferably, m falls within the range of 5-10 and n falls within the range of 5-10 and n falls within the range of 1-5. Most preferably m=6 and n=1. Y preferably indicates a CF₃ functional group. Y may be further modified to incorporate one or more substituents such as, vinyl, styryl, acryloyl, methacryloyl or alkyne for further functionalisation or cross-linking, with one or more spacer group such CH₂ to facilitate attachment.

According to the method of the present invention, compressed CO₂ may also be used to fabricate high denisty self-assembled monolayers of other simple alkane thiols and alkyl silane compounds.

The addition of co-solvents to the carbon dioxide such as H₂O, CH₃OH, CF₃OH, CF₃CH₂OH, CF₃CF₂OH, (CF₃)₂CHOH, CH₄, C₂H₄, C₂F₆, CHF₃ CCIF₃, C₂H₆, SF₆, Propylene, Propane, NH3, Pentane, ⁱPrOH, MeOH, EtOH, ¹BuOH, Benzene, Pyridine may also be adopted to provide further improvements in monolayer formation, such as faster and denser packing of the molecules constituting the monolayer.

The use of compressed CO₂ to form monolayers ensures that the complete functionalisation process of surfaces is performed without the use of any toxic, flammable or environmentally unfriendly solvents.

The following examples are provided to further explain the present invention:

### EXAMPLE 1

### Formation of Monolayers on Gold

A gold surface was prepared by evaporation of a 200 nm layer of gold onto a Si-wafer, with a 10 nm layer of Cr as an adhesive layer in between. The freshly evaporated gold surface was placed inside a stainless steel vessel such as that described, for example, by Hems et al in Journal of Materials Chemistry (1999) 9, 1403, together with 5 mg of CF₃(CF₂)₉(CH₂)₁₁SH. The vessel was initially filled with liquid CO₂ and then gradually heated to 35° C. to obtain the desired temperature and pressure. The mixture was left for approximately 30 minutes. The substrate in the cell was then rinsed by filling the cell two more times with liquid CO₂ and subsequent venting. The SAM fabricated in this example exhibited water contact angles of around 110° and an Ellipsometry thickness of around 30 Å.

### EXAMPLE 2

### Formation of Monolayers on Si

A clean Si wafer was placed inside a stainless steel vessel as described above with respect to Example 1, together with 1H,1H,2H,2H-perfluoredecyltrichlorosilane. The vessel was then filled with liquid CO₂ and then gradually heated to 35° C. to obtain the desired temperature and pressure. The mixture was left for approximately 30 minutes. The cell was cooled to room temperature and the CO₂ was vented. The substrate in the cell was rinsed by filling the cell two more times with liquid CO₂ and subsequent venting. The SAM fabricated in this example exhibited a dynamic water contact angle of around 110°, and an Ellipsometry thickness of around 30 Å.

It can be appreciated from examples 1 and 2 above that the monolayers can be fabricated in a relatively short period of time in comparison with known fabrication techniques using perfluorinated solvents. Furthermore, it will be appreciated by those skilled in this art that SAMs fabricated in accordance with the method of the present invention may be used in many applications where it is required to produce a flat impenetrable surface or where it is desirable to change the wettability characteristic of a surface. Hence, such monolayers can advantageously be used in the ink chambers of ink jet print heads to provide a dewetting surface on the gold surface usually provided to line such chambers to assist ejection. Also, being an impenetrable surface, the SAM also provides a protective layer for the gold surface in the corrosive environment found in such chambers arising from heating of the printing inks.

Additionally, SAMs fabricated in accordance with the present invention may also be used to modify the surface of a substrate upon which a thin film of an inorganic or organic material is required to be formed, such as in optical devices, optoelectronic devices, organic semiconductors, thin film transistors, LED or liquid crystal devices.

For semiconductor devices, the silicon substrate may act as a charge injecting layer and the monolayer, whilst providing the required surface structure for the substrate, is an extremely thin layer and hence electric charges required to operate the devices can be readily transmitted through the monolayer from the substrate.

Although the present invention has been described with reference to compressed carbon dioxide, it is to be appreciated that the method of the present invention can also be used under temperature and pressure conditions such that the carbon dioxide is in a supercritical condition. Furthermore, compressed carbon dioxide may be used to deposit the substance on the substrate and supercritical carbon dioxide may be used to subsequently enhance the density of the self-assembled monolayer, or vice versa. Therefore, as used in the context of the present invention, including the claims appended hereto, the term compressed carbon dioxide is intended to include also supercritical carbon dioxide.

The aforegoing description has been given by way of example only and it will be appreciated by a person skilled in the art that modifications can be made without departing from the scope of the present invention.

1. A method of fabricating a self-assembled monolayer of a substance on a substrate comprising depositing the substance on the substrate using compressed carbon dioxide as the solvent medium for the substance.

2. A method as claimed in claim 1, wherein the pressure and/or temperature of the compressed carbon dioxide is/are selectively controlled so as to enhance the density of the self-assembled monolayer on the substrate.

3. A method as claimed in claim 1 or 2 comprising the use of a co-solvent in combination with the compressed carbon dioxide.

4. A method as claimed in claim 3, wherein the co-solvent comprises at least one of H₂O, CH₃OH, CF₃OH, CF₃CH₂OH, CF₃CF₂OH, (CF₃)₂CHOH, CH₄, C₂H₄, C₂F₆, CHF₃ CCIF₃, C₂H₆, SF₆, Propylene, Propane, NH₃, Pentane, ⁱPrOH, MeOH, EtOH, ⁱBuOH, Benzene, Pyridine.

5. A method as claimed in any one of claims 1 to 4, wherein the substrate comprises a metallic substance.

6. A method as claimed in claim 5, wherein the metallic substance comprises at least one of gold, silver, copper, iron, mercury, palladium, gallium arsenide, ferrous oxide, indium tin oxide.

7. A method as claimed in claim 6, wherein the substance comprises a semi-fluorinated sulphur containing compound of the formula: 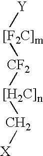
Where X comprises R—SH, RS—SR or R—S—R, where R denotes the rest of the molecule;
Y comprises a functional group; and
m and n denote respectively the number of fluorinated and non-fluorinated carbon atoms.

8. A method as claimed in claim 7, wherein X comprises a disulphide of sulphur.

9. A method as claimed in claim 7 or 8, wherein X comprises a thiol.

10. A method as claimed in any one of claims 7 to 9, wherein Y comprises a CF₃ functional group.

11. A method as claimed in any one of claims 7 to 10, wherein m and n lie within the range of 1 to 20.

12. A method as claimed in claim 11, wherein m and n lie within the range of 5 to 10.

13. A method as claimed in claim 12, where m is 8 and n is 10.

14. A method as claimed in any one of claims 7 to 13, wherein Y further comprises at least one of vinyl, styryl, acryloyl, methacryloyl or alkyne in combination with a spacer group.

15. A method as claimed in claim 14, wherein the spacer group comprises at least one of CH₂ or CF₂.

16. A method as claimed in any one of claims 1 to 5, wherein the substrate comprises at least one of glass, mica, SiO₂, A₂O₃, or Ga₂O₃.

17. A method as claimed in claim 16, wherein the substance comprises a semi-fluorinated silane derivative of the formula: 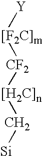
where Y comprises a functional group; and
m and n denote respectively the number of fluorinated and non-fluorinated carbon atoms.

18. A method as claimed in 17, wherein Si comprises a trialkoxy derivative.

19. A method as claimed in claim 18, wherein Si comprises at least one of SiCl₃, Si(OCH₃)₃, Si(OCH₂CH₃)₃, Si(OCH₃)₂Cl or Si(CH₂CH₃)₂Cl.

20. A method as claimed in any one of claims 17 to 19, wherein Y comprises a CF₃ functional group.

21. A method as claimed in any one of claims 17 to 19, wherein m and n lie within the range of 1 to 20.

22. A method as claimed in claim 21, wherein m and n lie within the range of 5 to 10.

23. A method as claimed in claim 22, wherein m is 6 and n is 1.

24. A method as claimed in any one of claims 17 to 23, wherein Y further comprises at least one of vinyl, styryl, acryloyl, methacryloyl or alkyne in combination with a spacer group.

25. A method as claimed in claim 24, wherein the spacer group comprises at least one of CH₂ or CF₂.

26. A method as claimed in any one of the preceding claims, wherein the self-assembled monolayer has an ellipsometry thickness of about 30 Å and a water contact angle of about 110°.

27. An inkjet head comprising a self-assembled monolayer as claimed in any one of claims 1 to 15 or claim 26, when appendant to any one of claims 1 to 15.

28. An electronic, optical or optoelectronic device comprising a self-assembled monolayer as claimed in any one of claims 1 to 5 or claims 16 to 26 or claim 26 when appendant to any one of claims 1 to 5, or 16 to 25.

29. A device as claimed in claim 28 comprising a thin film transistor or an organic semiconductor device, or a light emitting diode.

30. A device as claimed in claim 29, wherein the light emitting diode comprises an organic polymer light emitting diode.
